(19) United States
(12) Patent Application Publication
(10) Pub. No.: US 2020/0243401 A1
(43) Pub. Date: Jul. 30, 2020

(54) DISPLAY SUBSTRATE, DETECTION METHOD AND DETECTION APPARATUS

(71) Applicant: BOE TECHNOLOGY GROUP CO., LTD., Beijing (CN)

(72) Inventors: Tao WANG, Beijing (CN); Chunyan XIE, Beijing (CN)

(21) Appl. No.: 16/491,938

(22) PCT Filed: Jan. 4, 2019
(86) PCT No.: PCT/CN2019/070420

§ 371 Date: Sep. 6, 2019

(30) Foreign Application Priority Data
May 11, 2018 (CN) 201810449065.2

(51) Int. Cl. H01L 21/66; H01L 51/52; H01L 51/56; H01L 51/00

(52) U.S. Cl. CPC H01L 22/12; H01L 51/5253; H01L 51/0031; H01L 51/56; H01L 22/30

(57) ABSTRACT

The present disclosure provides a display substrate, a detection method and a detection apparatus. The display substrate includes a display region and a peripheral region surrounding the display region. The display substrate further includes a display element arranged at the display region, a thin film encapsulation layer covering the display element, and at least one detection structure arranged at the peripheral region. At least one detection structure which is not covered is configured to receive a light beam and generate a first reflected light beam. At least one detection structure which is covered by the thin film encapsulation layer is configured to receive the light beam and generate a second reflected light beam. A first optical parameter of the first reflected light beam is different from a second optical parameter of the second reflected light beam.

### CROSS-REFERENCE TO RELATED APPLICATION

The present application is the U.S. national phase of PCT Application No. PCT/CN2019/070420 filed on Jan. 4, 20919, which claims a priority to Chinese Patent Application No. 201810449065.2 filed on May 11, 2018, the disclosure of which are incorporated in their entirety by reference herein.

### TECHNICAL FIELD

The present disclosure relates to the field of display technology, in particular to a display substrate, a detection method and a detection apparatus.

### BACKGROUND

In the related art, due to such a characteristic as self-luminescence, a Liquid Crystal Display (LCD) and an Organic Light-Emitter Diode (OLED) display panel is capable of displaying an image in a curved state. When the OLED display panel includes a flexible substrate, it is able to display the image at a small bending radius. Hence, the manufacture of the OLED display panel including the flexible substrate has attracted more and more attention. Due to features of the flexible display device such as being light, thin and easy to be bent, many new applications of a flexible terminal device have emerged. When the flexible display product is bent, a display element or a control circuit region of the display element may be bent.

### SUMMARY

In one aspect, the present disclosure provides in some embodiments a display substrate, including a display region and a peripheral region surrounding the display region. The display substrate further includes a display element arranged at the display region, a thin film encapsulation layer covering the display element, and at least one detection structure arranged at the peripheral region. At least one detection structure which is not covered is configured to receive a light beam and generate a first reflected light beam. At least one detection structure which is covered by the thin film encapsulation layer is configured to receive the light beam and generate a second reflected light beam. A first optical parameter of the first reflected light beam is different from a second optical parameter of the second reflected light beam.

In a possible embodiment of the present disclosure, the at least one detection structure includes a plurality of detection structures surrounding the display element at a regular interval.

In a possible embodiment of the present disclosure, the at least one detection structure includes a plurality of detection structures surrounding the display element at a regular interval and arranged in two circles.

In a possible embodiment of the present disclosure, the display element is a polygon, and the at least one detection structure is arranged at the peripheral region at a position corresponding to a corner of the display element.

In a possible embodiment of the present disclosure, the display element is a polygon, and the at least one detection structure is arranged at the peripheral region at a position corresponding to a corner of the display element and at a position corresponding to a middle portion of at least one side of the polygon.

In a possible embodiment of the present disclosure, the at least one detection structure includes a plurality of detection structures which is divided into a plurality of groups of detection structures, and the detection structures in each group are arranged in a matrix form.

In a possible embodiment of the present disclosure, the at least one detection structure includes a plurality of detection structures, and a distance between two adjacent detection structures is 10 μm to 200 μm.

In a possible embodiment of the present disclosure, a cross section of the at least one detection structure is a square with each side having a length of 10 μm to 200 μm, and a height of the at least one detection structure is 1 μm to 10 μm.

In a possible embodiment of the present disclosure, the display substrate further includes: a retainer wall arranged at the peripheral region and surrounding the display element; and an anti-cracking groove arranged at a side of the retainer wall away from the display element. The at least one detection structure is arranged between the retainer wall and the anti-cracking groove.

In a possible embodiment of the present disclosure, a distance between the at least one detection structure and a side of the retainer wall away from the display element is 10 μm to 150 μm.

In another aspect, the present disclosure provides in some embodiments a detection method for the above-mentioned display substrate, including: prior to formation of the thin film encapsulation layer, transmitting a light beam to the at least one detection structure, receiving a first reflected light beam reflected from the at least one detection structure, and recording a first optical parameter of the first reflected light beam; subsequent to the formation of the thin film encapsulation layer on the display element, transmitting the light beam to the at least one detection structure, receiving a second reflected light beam reflected from the at least one detection structure, and recording a second optical parameter of the second reflected light beam; and when the first optical parameter is different from the second optical parameter, determining that at least one detection structure is covered by the thin film encapsulation layer.

In a possible embodiment of the present disclosure, the detection method further includes: subsequent to the formation of an organic material layer of the thin film encapsulation layer and prior to completion of the formation of the thin film encapsulation layer on the display element, transmitting the light beam to the at least one detection structure, receiving a third reflected light beam reflected from the at least one detection structure, and recording a third optical parameter of the third reflected light beam; and subsequent to recording the second optical parameter of the second reflected light beam, comparing the second optical parameter with the third optical parameter, and when the second optical parameter is identical to the third optical parameter, determining that an organic material of the organic material layer overflows; or subsequent to recording the second optical parameter of the second reflected light beam, acquiring a first difference between a first parameter in the second optical parameter and the first parameter in the first optical parameter, acquiring a second difference between the first parameter in the third optical parameter and the first parameter in the first optical parameter, comparing the first difference with the second difference, and when the first difference is identical to the second difference, determining that the organic material of the organic material layer overflows.

In yet another aspect, the present disclosure provides in some embodiments a detection apparatus for the above-mentioned display substrate, including: a detection light source configured to transmit a light beam to the at least one detection structure; and a reception device configured to receive a reflected light beam reflected from the at least one detection structure, and determine whether the at least one detection structure is covered by the thin film encapsulation layer in accordance with the reflected light beam reflected from the at least one detection structure.

In a possible embodiment of the present disclosure, the reception device is further configured to: prior to the formation of the thin film encapsulation layer, receive a first reflected light beam reflected from the at least one detection structure, and acquire a first optical parameter of the first reflected light beam; subsequent to the formation of the thin film encapsulation layer on the display element, receive a second reflected light beam reflected from the at least one detection structure, and acquire a second optical parameter of the second reflected light beam; and when the first optical parameter is different from the second optical parameter, determine that at least one detection structure is covered by the thin film encapsulation layer.

In a possible embodiment of the present disclosure, the reception device is further configured to: subsequent to the formation of an organic material layer of the thin film encapsulation layer and prior to the formation of the thin film encapsulation layer on the display element, receive a third reflected light beam reflected from the at least one detection structure, acquire a third optical parameter of the third reflected light beam, and when the second optical parameter is identical to the third optical parameter, determine that an organic material of the organic material layer overflows; or subsequent to recording the second optical parameter of the second reflected light beam, acquire a first difference between a first parameter in the second optical parameter and the first parameter in the first optical parameter, acquire a second difference between the first parameter in the third optical parameter and the first parameter in the first optical parameter, compare the first difference with the second difference, and when the first difference is identical to the second difference, determine that the organic material of the organic material layer overflows.

### BRIEF DESCRIPTION OF THE DRAWINGS

FIG. 1 is a sectional view of a conventional display substrate;

FIG. 2 is a topical top view of the display substrate in FIG. 1;

FIG. 3 is a sectional view of a display substrate according to one embodiment of the present disclosure;

FIG. 4 is a topical top view of the display substrate according to one embodiment of the present disclosure;

FIG. 5A is another top view of the display substrate according to one embodiment of the present disclosure;

FIG. 5B is yet another top view of the display substrate according to one embodiment of the present disclosure;

FIG. 5C is a topically enlarged view of section A of the display substrate in FIG. 5B;

FIG. 6 is still yet another top view of the display substrate according to one embodiment of the present disclosure;

FIG. 7 is still yet another top view of the display substrate according to one embodiment of the present disclosure;

FIG. 8 is still yet another top view of the display substrate according to one embodiment of the present disclosure;

FIG. 9 is a schematic view showing the cooperation of the display substrate with a detection apparatus when the display substrate is not covered by an organic material layer according to one embodiment of the present disclosure;

FIG. 10 is a schematic view showing the cooperation of the display substrate with the detection apparatus when the display substrate is covered by the organic material layer according to one embodiment of the present disclosure; and

FIG. 11 is a flow chart of a detection method for the display substrate according to one embodiment of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure.

Usually, a flexible display panel is encapsulated through a thin film encapsulation method. In the thin film encapsulation method, inorganic layers of a thin film encapsulation structure are formed through Plasma Enhanced Chemical Vapor Deposition (PECVD), sputtering or Atomic Layer Deposition (ALD), so as to provide resistance to moisture and oxygen. Due to the presence of a relatively large stress for each inorganic layer, usually an organic layer or the like may be added between two adjacent inorganic layers, so as to release the stress and achieve planarization.

Usually, the organic layer is formed through screen printing or inkjet printing. Due to the characteristics of an organic material, through the screen printing or inkjet printing, it is impossible to prevent the organic material from overflowing during the application and solidification. In the thin film encapsulation structure, the organic layer is sandwiched by the inorganic layers, and when the organic material overflows, the actual encapsulation reliability of the thin film encapsulation structure may be adversely affected. Hence, after the formation of the organic layer, it is necessary to detect whether the overflow occurs for the organic layer.

However, the organic layer has an excessively large transmittance, and it is difficult to detect whether the organic material of the organic layer overflows through a conventional detection method. In other words, the conventional detection method has a low detection rate, low detection efficiency and low detection accuracy.

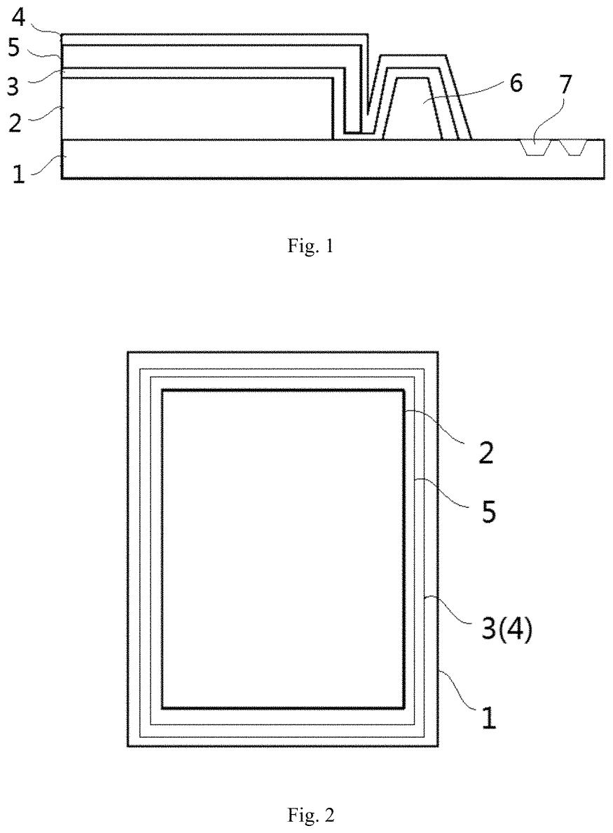

FIGS. 1 and 2 show a conventional display substrate. A display element is arranged on a substrate 1, and a thin film encapsulation structure is arranged at a side of the display element 2 away from the substrate 1. The thin film encapsulation structure includes a first inorganic layer 3, a second inorganic layer 4 and an organic layer 5. The first inorganic layer 3 is arranged at a side of the display element 2 away from the substrate 1. The second inorganic layer 4 is arranged at a side of the first inorganic layer 3 away from the display element 2 and separated from the first inorganic layer 3. The organic layer 5 is arranged between the first inorganic layer 3 and the second inorganic layer 4.

A retainer wall 6 is arranged surrounding the display element 2, so as to prevent the organic layer 5 from overflowing. A groove 7 is formed in the substrate 1, so as to prevent the occurrence of cracks for the substrate 1. Although with the retainer wall 6, it is still impossible to completely prevent the overflow of the organic layer 5 due to the characteristics of a manufacture process. When the overflow of the organic layer exceeds a certain level, a display function and usage of a display device may be adversely affected.

In a conventional method for detecting the overflow of the organic layer, a to-be-detected position of the substrate 1 is photographed so as to acquire an image of the to-be-detected position. Then, whether the organic layer overflows is determined through analyzing the image. However, the organic layer consists of a transparent liquid, so for the images acquired through a microscope, it is difficult to determine a difference between the image with the overflow of the organic layer and the image without the overflow of the organic layer, resulting in an inaccurate detection result. Hence, it is difficult to detect the overflow of the organic layer, the detection result acquired through the detection method or device is inaccurate, and the detection efficiency is low.

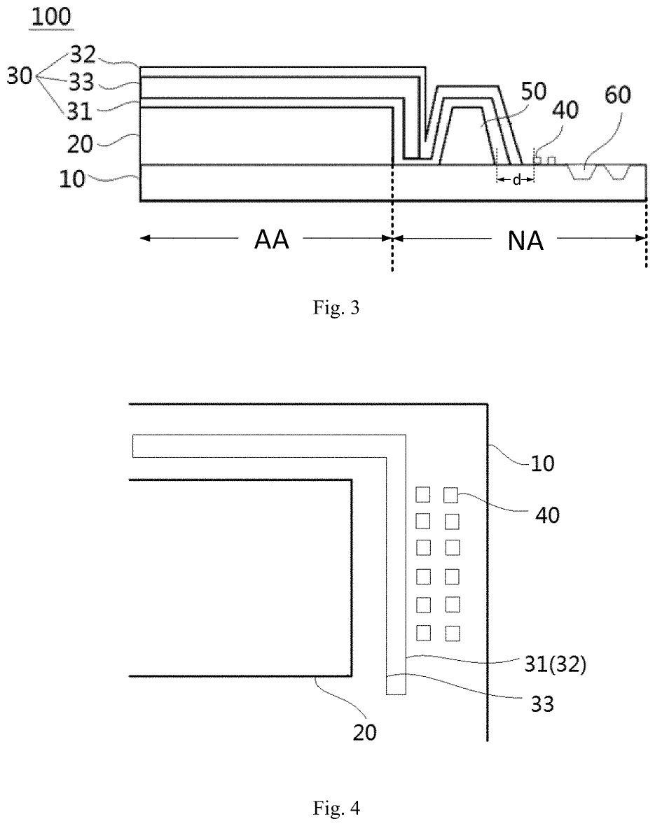

The present disclosure provides in some embodiments a display substrate 100. As shown in FIGS. 3 and 4, the display substrate 100 includes a display region AA and a peripheral region NA surrounding the display region AA. The display substrate 100 further includes a display element 20, a thin film encapsulation layer 30 and at least one detection structure 40. The display element 20 is arranged at the display region AA, the thin film encapsulation layer 30 covers the display element 20, and the at least one detection structure 40 is arranged at the peripheral region NA.

When the at least one detection structure 40 is not covered, it may receive a light beam and generate a first reflected light beam. When at least a part of the at least one detection structure 40 is covered by the thin film encapsulation layer 30, the at least one detection structure 40 may receive the light beam and generate a second reflected light beam. An optical parameter of the first reflected light beam may be different from that of the second reflected light beam.

A parameter type of the first optical parameter may be the same as that of the second optical parameter. When the first optical parameter is different from the second optical parameter, it means that a value of a parameter included in the first optical parameter is different from a value of a parameter included in the second optical parameter.

In some embodiments of the present disclosure, the display substrate 100 may further include a substrate 10, and the display region and the peripheral region may be arranged on the substrate 10.

In some embodiments of the present disclosure, the display region AA may be a square, and the display element 20, which is also a square, may be arranged at the display region AA.

In a possible embodiment of the present disclosure, the display element may be a rectangle, circle or oval.

In some embodiments of the present disclosure, the display element 20 may be an OLED display element.

In some embodiments of the present disclosure, the thin film encapsulation layer 30 may include inorganic material layers and an organic material layer 33 arranged between the inorganic material layers.

When the organic material layer 33 is arranged between the inorganic material layers, it is able to reduce a stress generated in each inorganic material layer.

In some embodiments of the present disclosure, the inorganic material layers may include a first inorganic material layer 31 and a second inorganic material layer 32. The first inorganic material layer 31 may be arranged at a side of the display element 20 away from the substrate 10. The second inorganic material layer 32 may be separated from the first inorganic material layer 31 and arranged at a side of the first inorganic material layer 31 away from the display element 20. The organic material layer 33 may be arranged between the first inorganic material 31 and the second inorganic material layer 32.

When the organic material layer 33 is arranged between the inorganic material layers, it is able to reduce, through the organic material layer, a stress generated in each inorganic material layer.

In some embodiments of the present disclosure, the at least one detection structure 40 may be arranged at a to-be-detected position.

The at least one detection structure 40 may be arranged at a periphery of the display element 20 and separated from the display element 20 by a certain distance. When an organic material overflows, it may cover the detection structure 40.

In some embodiments of the present disclosure, the detection structure 40 may be a reflective member, and it may receive and reflect the light beam.

When the light beam reaches the detection structure 40, the detection structure 40 may reflect the light beam. To be specific, when the detection structure 30 is not covered, it may receive the light beam and generate the first reflected light beam.

In some embodiments of the present disclosure, the optical parameter of the first reflected light beam may be acquired by a detection apparatus.

When at least a part of the detection structure 40 is covered by the thin film encapsulation layer 30, the detection structure 40 may receive the light beam and generate the second reflected light beam. The optical parameter of the second reflected light beam may be acquired by the detection apparatus.

When at least a part of the detection structure 40 is covered, e.g., by the organic material, the organic material is different from a material of the detection structure 40, so the organic material may have a reflectivity, a refractive index and a light absorption rate different from the detection structure 40. In other words, the light beam may be reflected, refracted and absorbed by the organic material in a way different from the detection structure 40.

When a part of the light beam reaches the organic material, the optical parameter of the second reflected light beam may be different from that of the first reflected light beam.

In some embodiments of the present disclosure, the first optical parameter and the second optical parameter may include same optical parameters. The first optical parameter may include at least one of an emergent angle, an intensity and a wave vector of the first reflected light beam.

In some embodiments of the present disclosure, each of the first optical parameter and the second optical material may include a plurality of optical parameters, and some of the optical parameters in the first optical parameter, e.g., the emergent angle and the intensity, may be different from those in the second optical parameter. When the first optical parameter of the first reflected light beam is different from the second optical parameter of the second reflected light beam, it means that the emergent angle in the first optical parameter is different from that in the second optical parameter, and the intensity of the light in the first optical parameter is different from that in the second optical parameter.

In the embodiments of the present disclosure, whether the detection structure 40 is covered and whether the organic material in an encapsulation structure overflows may be determined in accordance with the first optical parameter and the second optical parameter.

Each of the first optical parameter and the second optical parameter may include a plurality of parameters, so it is able to avoid inaccurate detection result caused by errors in some parameters, thereby to improve the detection efficiency.

According to the display substrate 100 in the embodiments of the present disclosure, the display substrate 100 may include at least one detection structure 40, and the detection structure 40 may receive the light beam and generate the reflected light beam. Since the optical parameter of the reflected light beam generated when the detection structure 40 is not covered is different from the optical parameter of the reflected light beam generated when the detection structure 40 is covered, it is able to accurately determine whether the detection structure 40 is covered. As a result, it is able to improve the detection efficiency and the accuracy of the detection result, thereby to ensure the actual encapsulation reliability of the thin film encapsulation structure.

In some embodiments of the present disclosure, the at least one detection structure 40 may include a plurality of detection structures 40.

In some embodiments of the present disclosure, the plurality of detection structures 40 may surround the display element 20 at a regular interval, i.e., any two adjacent detection structures 40 may be separated from each other by a same distance.

In some embodiments of the present disclosure, the plurality of detection structures 40 may surround the display element 20 in one circle.

In some embodiments of the present disclosure, when the detection structures 40 surround the display element 20 in one circle, any two adjacent detection structures 40 at each side of the display element 20 may be separated from each other by a same distance.

In some embodiments of the present disclosure, when the detection structures 40 surround the display element 20 in one circle, any two adjacent detection structures 40 may be separated from each other by 10 μm to 200 μm.

An appropriate distance between two adjacent detection structures 40 may be selected. When the distance is too large and the organic material overflows, the organic material may not cover the detection structure 40 but may be filled between the two detection structures 40. At this time, an inaccurate detection result may be acquired. Through setting the appropriate distance, it is able to accurately determine whether the organic material overflows.

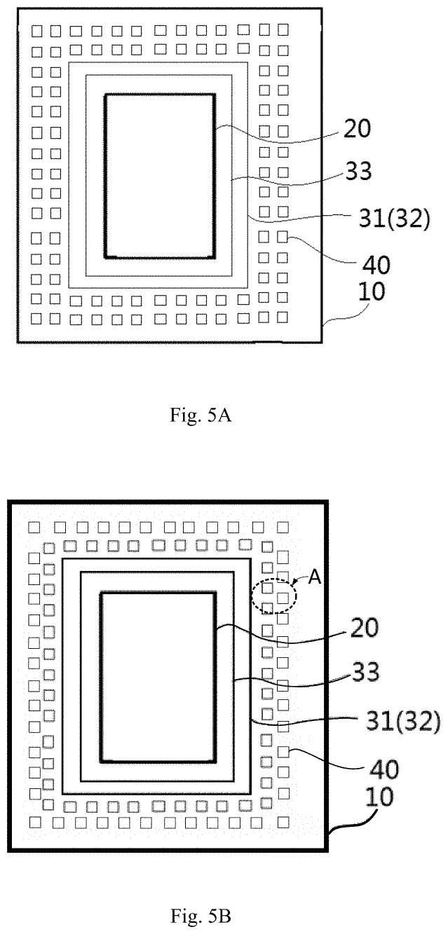

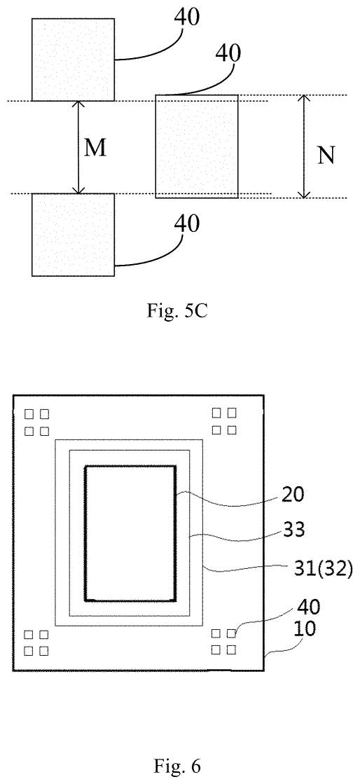

In some embodiments of the present disclosure, as shown in FIGS. 5A and 5B, the at least one detection structure 40 may include a plurality of detection structures 40 which may surround the display element 20 at a regular interval and may be arranged in two circles.

When the detection structures 40 surround the display element 20 in two circles, it is able to improve the detection accuracy.

In some embodiments of the present disclosure, as shown in FIG. 5A, for the detection structures 40 surrounding the display element 20 in each circle, any two adjacent detection structures 40 at each side of the display element 20 may be separated from each other by a same distance.

In some embodiments of the present disclosure, as shown in FIG. 5A, a first circle of detection structures 40 may surround the display element 20 and may be arranged adjacent to the display element 20, and a second circle of detection structures 40 may surround the display element 20 and may be arranged away from the display element 20. At each side of the display element 20, each detection structure in the first circle may be separated from a corresponding detection structure in the second circle by a same distance.

In some embodiments of the present disclosure, as shown in FIG. 5B, each detection structure 40 in the second circle away from the display element 20 may be arranged at a position corresponding to a gap between two adjacent detection structures 40 in the first circle adjacent to the display element 20.

In some embodiments of the present disclosure, as shown in FIG. 5C, a distance M between any two adjacent detection structures 40 in the first circle may be smaller than or equal to a length N of a side of each detection structure 40 in the second circle adjacent to the first circle, where M and N are each greater than 0.

When the organic material overflows between the two adjacent detection structures 40 in the first circle but does not cover the detection structures in the first circle, it may cover the detection structures 40 in the second circle. In this way, it is able to accurately determine whether the organic material overflows.

In some embodiments of the present disclosure, the display element 20 is a polygon, e.g., rectangle or square. The detection structure 40 may be arranged at a peripheral region at a position corresponding to a corner of the display element 20. A plurality of detection structures 40 may be arranged at the peripheral region corresponding to at least one corner.

For example, the display element 20 may be a rectangle, and the peripheral region NA may also be a rectangle. A corner of the peripheral region NA may surround a corresponding corner of the display element 20, and the detection structure 40 may be arranged at the corner of the peripheral region surrounding the corresponding corner of the display element 20.

In some embodiments of the present disclosure, as shown in FIG. 6, the display element 20 may be a rectangle, and the detection structure 40 may be arranged at a position corresponding to each of the four corners of the display element 20. To be specific, four detection structures 40 may be arranged at the peripheral region at a position corresponding to each corner of the display element 20.

When the detection structure at the peripheral region corresponding to each corner of the display element is covered by the organic material, it is able to accurately determine that the organic material overflows.

In some embodiments of the present disclosure, the display element 20 may be a polygon, e.g., rectangle or square. The detection structures 40 may be arranged at the peripheral region at positions corresponding to the corners of the display element 20 and at a position corresponding to a middle portion of at least one side of the display element 20.

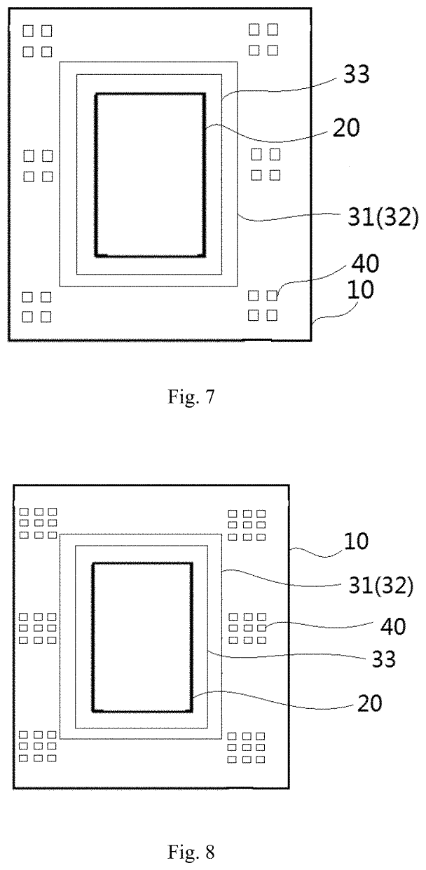

As shown in FIG. 7, the display element 20 may be rectangle, and a plurality of detection structures 40, e.g., four detection structures 40, may be arranged at the peripheral region at a position corresponding to each corner of the display element 20. In addition, a plurality of detection structures 40, e.g., four detection structures 40, may be arranged at the peripheral region at a position corresponding to a middle portion of each side of the display element.

For example, when the display element 20 is provided with corners, the peripheral region NA may also be provided with corners, and each corner of the display region NA may surround a corresponding corner of the display element 20. All sides of the display element 20 may be surrounded by the peripheral region NA, and the detection structures 40 may be arranged at each corner of the peripheral region surrounding the corresponding corner of the display element 20, and at the peripheral region at a position corresponding to the middle portion of at least one side of the display element 20.

When the detection structures are arranged at each corner of the peripheral region and at a position corresponding to the middle portion of each side of the display element, it is able to accurately determine whether the organic material overflows and covers the detection structures 40.

In some embodiments of the present disclosure, the detection structures 40 may be divided into a plurality of groups, and each group of detection structures 40 may be arranged in matrix.

For example, a group of detection structures 40 may be arranged at the peripheral region at a position corresponding to each corner of the display element and at a position corresponding to the middle portion of each side of the display element, and each group may include a plurality of detection structures 40. As shown in FIG. 7, each group may include four detection structures 40 arranged in two rows and two columns. As shown in FIG. 8, each group may include nine detection structures 40 arranged in three rows and three columns.

When the detection structures 40 are arranged in a matrix form, it is able to improve the detection accuracy when the organic material overflows.

In some embodiments of the present disclosure, a distance between two adjacent detection structures 40 may be 10 μm to 200 μm.

For example, the distance between two adjacent detection structures 40 may be 20 μm. The smaller the distance between the two adjacent detection structures 40, the higher the detection accuracy.

In some embodiments of the present disclosure, a first region of the peripheral region on the substrate 1 where no detection structure 40 is arranged may be made of a reflective material.

When the first region is made of the reflective material, it may reflect the light beam. When the organic material overflows at a small amount and does not cover the detection structure 40, the organic material may cover the first region. When the light beam reaches the first region, an optical parameter of a reflected light beam reflected from the first region covered by the organic material may be different from that of a reflected light beam reflected from the first region not covered by the organic material. Whether the organic material overflows to the peripheral region may be determined in accordance with the optical parameters. In this way, it is able to improve the detection accuracy and reliability.

In some embodiments of the present disclosure, a portion of the substrate 1 adjacent to the detection structure 40 is capable of reflecting the light beam.

For example, a portion of the substrate 1 within a range of 30 μm from an edge of the detection structure 40 may be configured to reflect the light beam. In this way, it is able to determine whether the organic material overflows at a region surrounding the detection structure, thereby to improve the detection accuracy.

In some embodiments of the present disclosure, a cross section of the detection structure 40 is a rectangle, and the detection structure 40 may be provided with an appropriate length or width, e.g., 10 μm to 200 μm.

For example, the cross section of the detection structure 40 may be a square with a side length of 10 μm.

In some embodiments of the present disclosure, the cross section of the detection structure 40 may be a rectangle, trapezoid or circle.

The light beam generated by the detection apparatus may reach the detection structures 40 uniformly, so as to accurately determine whether the organic material covers the detection structures 40.

In some embodiments of the present disclosure, the detection structure 40 may have a height of 1 μm to 10 μm.

The detection structure 40 shall not be too much high. When the height of the detection structure is too large and the organic material overflows, the organic material may not cover the detection structure 40. At this time, the detection accuracy may be adversely affected.

In some embodiments of the present disclosure, the height of the detection structure 40 may be 1 μm. At this time, the organic material may cover the detection structure 40 even when the organic material overflows at a small amount, so as to improve the detection accuracy.

The distance between two adjacent detection structures 40 and the size of the detection structure 40 may depend on a quarter wavelength of the light beam received by the detection structure 40. In other words, the appropriate distance and size may be selected in accordance with the wavelength of the actual light beam, so as to ensure the wavelength to match the detection structure 40, thereby to improve the detection accuracy.

In some embodiments of the present disclosure, as shown in FIG. 3, a retainer wall 50 surrounding the display element 20 may be arranged at the peripheral region.

In some embodiments of the present disclosure, the retainer wall 50 may be a quadrangular prism with a trapezoidal longitudinal section. The retainer wall 50 is provided to prevent the overflow of the organic material.

In some embodiments of the present disclosure, an anti-cracking groove 60 may be arranged at a side of the retainer wall 50 away from the display element 2.

In some embodiments of the present disclosure, the anti-cracking groove 60 may be arranged at the peripheral region in two circles separated from each other.

In some embodiments of the present disclosure, a longitudinal section of the anti-cracking groove 60 may be a trapezoid or isosceles trapezoid, a size of a lower base of the trapezoid at a bottom of the anti-cracking groove 60 may be greater than a size of an upper base of the trapezoid at an opened end of the anti-cracking groove 60. In this way, it is able to prevent the occurrence of cracks in the substrate.

In some embodiments of the present disclosure, the detection structure 40 may be arranged between the retainer wall 50 and the anti-cracking groove 60. When the organic material overflows beyond the retainer wall 50, the detection apparatus is able to accurately determine that the organic material overflows.

In some embodiments of the present disclosure, the display substrate 100 may be provided with merely the retainer wall 50 rather than the anti-cracking groove 60, and the detection structure 40 may be arranged outside the retainer wall 50.

In some embodiments of the present disclosure, the display substrate 100 may be provided with merely the anti-cracking groove 60 rather than the retainer wall 50, and the detection structure 40 may be arranged between the display element 20 and the anti-cracking groove 60, or outside the anti-cracking groove 60.

When the detection structure 40 is arranged outside the anti-cracking groove 60, the organic material may flow into the anti-cracking groove 60, so it is able to prevent the organic material from flowing continuously to the other portion of the peripheral region. When the anti-cracking groove 60 is filled with the organic material, the organic material may at least cover a part of the detection structure 40, so the detection apparatus is able to accurately determine that the organic material overflows.

In some embodiments of the present disclosure, as shown in FIG. 3, a distance d between the detection structure 40 closest to the display element 20 and a side of the retainer wall 50 away from the display element 20 may be 10 μm to 150 μm.

For example, the distance between the detection structure 40 closest to the display element 20 and the retainer wall 50 may be 10 μm. At this time, it is able to accurately determine whether the organic material overflows onto the detection structure 40.

According to the display substrate 100 in the embodiments of the present disclosure, the display substrate 100 may include the detection structure 40. The detection structure 40 may receive the light beam and generate the reflected light beam. The optical parameter of the reflected light beam generated when the detection structure 40 is not covered may be different from the optical parameter of the reflected light beam generated when the detection structure 40 is covered, so it is able to accurately determine whether the detection structure 40 is covered, thereby to determine whether the organic material in the thin film encapsulation layer overflows. By providing the retainer wall 50, it is able to prevent the overflow of the organic material, and by providing the anti-cracking groove 60, it is able to prevent the occurrence of the cracks for the substrate. As a result, it is able to determine whether the organic material overflows in an easy manner, thereby to improve the detection efficiency and the detection accuracy, and ensure the actual encapsulation reliability of the thin film encapsulation structure.

The present disclosure further provides in some embodiments a detection method for the above-mentioned display substrate 100.

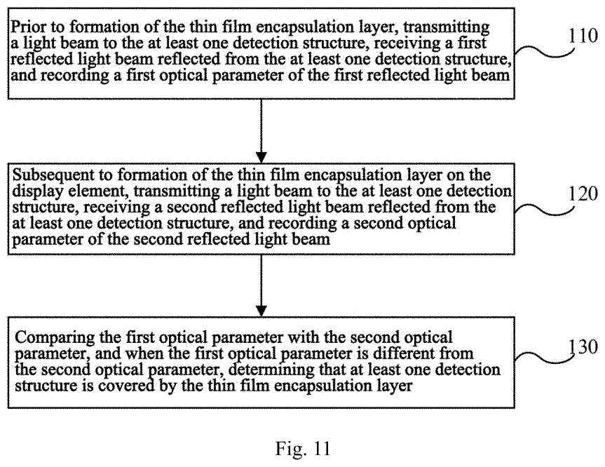

As shown in FIG. 11, the detection method includes: Step 110 of, prior to the formation of the thin film encapsulation layer, transmitting a light beam to the at least one detection structure 40, receiving a first reflected light beam reflected from the at least one detection structure 40, and recording a first optical parameter of the first reflected light beam; Step 120 of, subsequent to the formation of the thin film encapsulation layer on the display element, transmitting the light beam to the at least one detection structure 40, receiving a second reflected light beam reflected from the at least one detection structure, and recording a second optical parameter of the second reflected light beam; and Step 130 of comparing the first optical parameter with the second optical parameter, and when the first optical parameter is different from the second optical parameter, determining that at least one detection structure is covered by the thin film encapsulation layer.

Prior to the formation of the thin film encapsulation layer, the light beam may be transmitted to the detection structure 40 at a certain incident angle. Then, the first reflected light beam reflected from the detection structure 40 may be received, and the first optical parameter of the first reflected light beam may be recoded. The first optical parameter may include at least one of an intensity, an angle and a wave vector of the first reflected light beam.

Subsequent to the formation of the thin film encapsulation layer on the display element, the light beam, which has a same parameter as that transmitted to the detection structure prior to the thin film encapsulation layer, may be transmitted to the detection structure 40 again, the second reflected light beam reflected from the detection structure 40 may be received, and the second optical parameter of the second reflected light beam may be recoded. The second optical parameter may include at least one of an intensity, an angle and a wave vector of the second reflected light beam.

The first optical parameter may be compared with the second optical parameter. When the first optical parameter is different from the second optical parameter, the at least one detection structure 40 may be covered by the organic material. In this way, it is able to determine whether the organic material in the thin film encapsulation layer overflows.

For example, when the organic material does not overflow, the first optical parameter may be identical to the second optical parameter. When the organic material overflows, because the organic material has a reflectivity, a refractive index and a light absorption rate different from the detection structure 40, the first optical parameter may be different from the second optical parameter. Each of the first optical parameter and the second optical parameter may include an intensity, an angle and a wave vector of the reflected light beam. Through comparing a plurality of parameters, it is able to improve the detection accuracy. Whether the detection structure 40 is covered by the organic material may be determined in accordance with the first optical parameter and the second optical parameter, so it is able to improve the detection accuracy as well as the detection efficiency.

In some embodiments of the present disclosure, subsequent to the formation of an organic material layer of the thin film encapsulation layer and prior to the formation of the thin film encapsulation layer on the display element, the detection method may further includes transmitting the light beam to the at least one detection structure, receiving a third reflected light beam reflected from the at least one detection structure, recording a third optical parameter of the third reflected light beam, and when the second optical parameter is identical to the third optical parameter, determining that the organic material in the thin film encapsulation layer overflows.

In some embodiments of the present disclosure, each of the second optical parameter and the third optical parameter may include an intensity, an angle and a wave vector of the reflected light beam.

When each of the second optical parameter and the third optical parameter includes the intensity, the angle and the wave vector of the reflected light beam and the second optical parameter is identical to the third optical parameter, it means that the intensity of the reflected light beam in the second optical parameter may be the same as that in the third optical parameter, the angle in the second optical parameter may be the same as that in the third optical parameter, and the wave vector in the second optical parameter may be the same as that in the third optical parameter.

When the organic material overflows and covers the detection structure 40, at least a part of the light beam may be reflected and absorbed by the organic material, so that the optical parameter of the reflected light beam may be different from the optical parameter of the reflected light beam reflected from the detection structure 40 which is not covered. For example, after a part of the light beam has been absorbed by the organic material layer, the intensity of the reflected light beam may decrease.

In some embodiments of the present disclosure, subsequent to recording the second optical parameter of the second reflected light beam, the detection method may further include acquiring a first difference between a first parameter in the second optical parameter and the first parameter in the first optical parameter, acquiring a second difference between the first parameter in the third optical parameter and the first parameter in the first optical parameter, comparing the first difference with the second difference, and when the first difference is identical to the second difference, determining that the organic material of the organic material layer overflows.

In some embodiments of the present disclosure, the first parameter may include at least one optical parameter.

For example, the first parameter may include the intensity and the wave vector of the reflected light beam. When the intensity of the reflected light beam in the second optical parameter is decremented by A as compared with the intensity of the reflected light beam in the first optical parameter, and the intensity of the reflected light beam in the third optical parameter is decremented by A as compared with the intensity of the reflected light beam in the first optical parameter, it can be determined that the organic material in the thin film encapsulation layer overflows.

According to the detection method in the embodiments of the present disclosure, it is able to accurately determine whether the detection structure 40 is covered and whether the organic material overflows, thereby to improve the detection accuracy as well as the detection efficiency.

The present disclosure further provides in some embodiments a detection apparatus for the above-mentioned display substrate 100, which includes a detection light source 70 and a reception device 80.

The display substrate 100 may include a display region and a peripheral region surrounding the display region. The display element 20 may be arranged at the display region. The display substrate 100 may further include the thin film encapsulation layer 30 covering the display element 20, and detection structures 40 arranged at the peripheral region.

The detection light source 70 is configured to transmit a light beam to the detection structure 40 at a certain incident angle. The other parameters of the light beam may be constant.

In some embodiments of the present disclosure, the detection light source 70 is configured to transmit the light beam to the detection structure 40 intermittently.

In some embodiments of the present disclosure, the detection light source 70 is configured to transmit the light beam to the detection structure 40 continuously.

In some embodiments of the present disclosure, in order to save power and prolong a service life of the detection light source, the detection light source may transmit the light beam to the detection structure intermittently. To be specific, the light beams having a same optical parameter may be transmitted to the detection structure 40 before and after the formation of the thin film encapsulation layer, so as to prevent the occurrence of an error for the detection result when the light beams have different parameters.

The reception device 80 is configured to receive a reflected light beam reflected from the detection structure 40, determine whether the detection structure 40 is covered by the thin film encapsulation layer in accordance with the reflected light beam reflected from the detection structure 40, and determine whether the organic material in the thin film encapsulation layer overflows in accordance with the optical parameter of the reflected light beam.

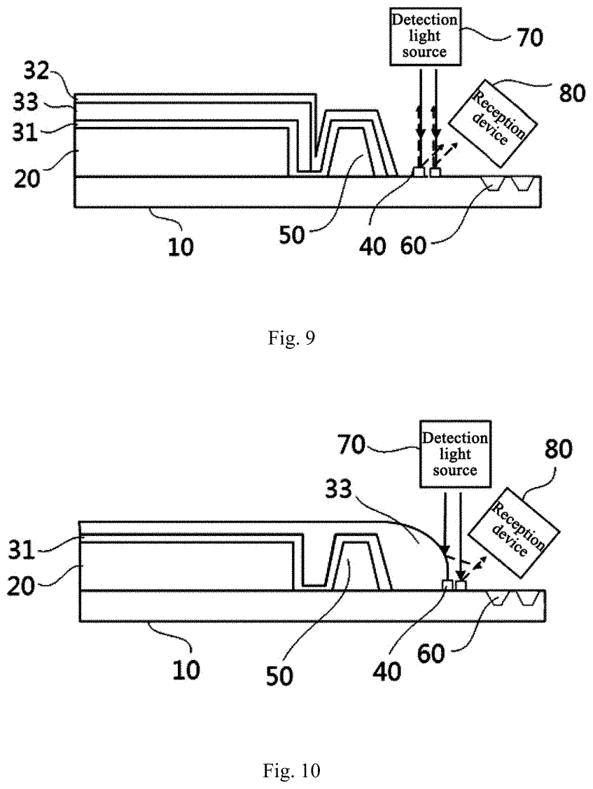

In some embodiments of the present disclosure, as shown in FIG. 9, prior to the formation of the thin film encapsulation layer, the detection structure 40 may not be covered by the thin film encapsulation layer. The detection light source 70 may transmit the light beam to the detection structure 40. The detection structure 40 reflects the transmitted light beam. The reception device 80 may receive the first light beam reflected from the detection structure 40, and acquire the first optical parameter of the first reflected light beam. The first optical parameter may include at least one of an intensity, an angle and a wave vector of the first reflected light beam.

For example, the first optical parameter may include the intensity, the angle and the wave vector of the first reflected light beam, and compare a plurality of the parameters in the first optical parameter with a plurality of parameters in the second optical parameter. In this way, it is able to improve the detection accuracy.

Subsequent to the formation of the thin film encapsulation layer on the display element, the detection light source 70 may transmit the light beam to the detection structure 40. The reception device 80 may receive the second reflected light beam reflected from the detection structure 40, and acquire the second optical parameter of the second reflected light beam. The second optical parameter may include at least one of an intensity, an angle and a wave vector of the second reflected light beam.

For example, the first optical parameter may include the intensity, the angle and the wave vector of the first reflected light beam, and compare a plurality of the parameters in the first optical parameter with a plurality of parameters in the second optical parameter. In this way, it is able to improve the detection accuracy.

When the detection structure 40 is not covered by the thin film encapsulation layer, the second optical parameter may be the same as the first optical parameter. When a part of the detection structure 40 is covered by the thin film encapsulation layer (e.g., when the organic material in the thin film encapsulation layer overflows as shown in FIG. 10, a part of the detection structure 40 may be covered by the organic material), the light beam reflected from the detection structure 40 may change, and the second optical parameter may change accordingly. For example, an emergent angle of the reflected light beam may change, i.e., a part of the light beam may be reflected at a different angle, and the intensity of the other part of the light beam reflected at a same angle as the light beam reflected when the detection structure is not covered may decrease.

The reception device 80 is configured to compare the first optical parameter with the second optical parameter, and determine whether the detection structure is covered in accordance with a comparison result. For example, the reception device 80 may compare the intensities of the reflected light beam before and after the formation of the thin film encapsulation layer, and if a difference between the intensities exceeds a predetermined value, determine that the detection structure is covered.

In some embodiments of the present disclosure, each of the first optical parameter and the second optical parameter may include the intensity, the angle and the wave vector of the reflected light beam.

Each of the first optical parameter and the second optical parameter may include a plurality of parameters, so it is able to improve the accuracy of the detection result event when there are errors for some of the parameters, thereby to improve the detection efficiency.

When the organic material does not overflow or overflows at a very small amount and does not cover the detection structure 40, the optical parameter of the light beam reflected from the detection structure 40 shall be identical to the first optical parameter. When the optical parameter of the light beam reflected from the detection structure 40 is different from the first optical parameter, it means that at least a part of the detection structure 40 is covered by the organic material or any other materials.

In some embodiments of the present disclosure, when at least a part of the detection structure 40 is covered by the organic material in the thin film encapsulation layer, the third optical parameter of the third reflected light beam may be acquired. The reception device 80 is further configured to, when the second optical parameter is identical to the third optical parameter, determine that the organic material in the thin film encapsulation layer overflows.

In some embodiments of the present disclosure, when the third optical parameter is identical to the second optical parameter, it means that the detection structure 40 is covered by the organic material of the organic material layer and the overflow occurs for the organic material.

Through comparing the optical parameters of the light beams reflected from the detection structure 40 before and after the formation of the thin film encapsulation layer, it is able to accurately determine whether the organic material overflows, thereby to improve the detection accuracy and the detection efficiency.

In some embodiments of the present disclosure, after the reflected light beam passes through the organic material, the intensity, the angle, the wave vector or any other property of the light beam reflected from the detection structure may change. The reception device is further configured to acquire a first difference between a first parameter in the second optical parameter (e.g., the intensity, the angle, the wave vector or any other property of the reflected light beam) and the first parameter in the first optical parameter, acquire a second difference between the first parameter in the third optical parameter and the first parameter in the first optical parameter, compare the first difference with the second difference, and when the first difference is identical to the second difference, determine that the detection structure 40 is covered by the organic material, i.e., the organic material of the organic material layer overflows.

For example, when the light beam at a certain wavelength has been absorbed and the intensity in the second optical parameter and the third optical parameter change accordingly, it may be determined that the detection structure 40 is covered by the organic material.

In some embodiments of the present disclosure, prior to the formation of the thin film encapsulation layer, the detection light source 70 may transmit a laser beam to the detection structure 40. The reception device 80 may receive the first reflected light beam reflected from the detection structure 40, and acquire the first optical parameter of the first reflected light beam. After the formation of the thin film encapsulation layer, the detection light source 70 may transmit a laser beam with a same parameter as that transmitted before the formation of the thin film encapsulation layer. The reception device 80 may receive the second reflected light beam reflected from the detection structure, acquire the second optical parameter of the second reflected light beam, and compare the first optical parameter with the second optical parameter. Each of the first optical parameter and the second optical parameter may include the intensity, the angle and the wave vector of the reflected light beam.

When the first optical parameter is identical to the second optical parameter, it means that the detection structure 40 is not covered by the organic material. When the first optical parameter is different from the second optical parameter, it means that at least a part of the detection structure 40 is covered by the organic material.

When the laser beam having the same parameter as that transmitted when the detection structure 40 is not covered is transmitted to the detection structure 40, subsequent to the formation of the organic material layer of the thin film encapsulation layer and prior to the formation of the thin film encapsulation layer on the display element, the reception device 80 may receive the third reflected light beam reflected from the detection structure 40, acquire the third optical parameter of the third reflected light beam, and when the second optical parameter is identical to the third optical parameter, determine that the organic material in the organic material layer overflows.

In some embodiments of the present disclosure, the reception device 80 is further configured to, subsequent to recoding the second optical parameter of the second reflected light beam, acquire a first difference between the first parameter in the second optical parameter and the first parameter in the first optical parameter, acquire a second difference between the first parameter in the third optical parameter and the first parameter in the first optical parameter, compare the first difference with the second difference, and if the first difference is identical to the second difference, determine that the organic material of the organic material layer overflows.

In some embodiments of the present disclosure, the third optical parameter may include an intensity, an angle and a wave vector of the third reflected light beam. When the intensity, the angel and the wave vector in the third reflected light beam are the same as those in the second optical parameter respectively, the reception device 80 may determine that the organic material overflows.

In some embodiments of the present disclosure, the light beam transmitted by the detection light source 70 to the detection structure 40 may be an infrared light beam.

According to the detection apparatus in the embodiments of the present disclosure, the detection structure 40 may receive the light beam and generate the reflected light beam. The optical parameter of the reflected light beam generated when the detection structure 40 is not covered may be different from the optical parameter of the reflected light beam generated when the detection structure 40 is covered, so it is able to accurately determine whether the detection structure 40 is covered, and determine whether the organic material in the thin film encapsulation layer overflows. As a result, it is able to improve the detection efficiency and the detection accuracy, thereby to ensure the actual encapsulation reliability of the thin film encapsulation structure.

According to the detection method in the embodiments of the present disclosure, it is able to determine whether the detection structure 40 on the display substrate is covered, thereby to accurately determine whether the organic material in the thin film encapsulation layer overflows in a simple and convenient manner.

The detection light source 70 of the detection apparatus may transmit the light beam to the detection structure. The reception device 80 may receive the light beam reflected from the detection structure, determine whether the detection structure 40 is covered in accordance with the reflected light beam, and then determine whether the organic material overflows. Through the detection method and the detection apparatus in the embodiments of the present disclosure, it is able to accurately determine whether the detection structure 40 is covered and whether the organic material in the thin film encapsulation layer overflows, thereby to improve the detection accuracy and reduce the influence caused when the detection result is inaccurate.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A display substrate, comprising a display region and a peripheral region surrounding the display region, wherein the display substrate further comprises a display element arranged at the display region, a thin film encapsulation layer covering the display element, and at least one detection structure arranged at the peripheral region;
at least one detection structure which is not covered is configured to receive a light beam and generate a first reflected light beam;
at least one detection structure which is covered by the thin film encapsulation layer is configured to receive the light beam and generate a second reflected light beam; and
a first optical parameter of the first reflected light beam is different from a second optical parameter of the second reflected light beam.

2. The display substrate according to claim 1, wherein the at least one detection structure comprises a plurality of detection structures surrounding the display element at a regular interval.

3. The display substrate according to claim 1, wherein the at least one detection structure comprises a plurality of detection structures surrounding the display element at a regular interval and arranged in two circles.

4. The display substrate according to claim 1, wherein the display element is a polygon, and the at least one detection structure is arranged at the peripheral region at a position corresponding to a corner, of the display element.

5. The display substrate according to claim 1, wherein the display element is a polygon, and the at least one detection structure is arranged at the peripheral region at a position corresponding to a corner of the display element and at a position corresponding to a middle portion of at least one side of the polygon.

6. The display substrate according to claim 1, wherein the at least one detection structure comprises a plurality of detection structures which is divided into a plurality of groups of detection structures, and the detection structures in each group are arranged in a matrix form.

7. The display substrate according to claim 1, wherein the at least one detection structure comprises a plurality of detection structures, and a distance between two adjacent detection structures is 10 μm to 200 μm.

8. The display substrate according to claim 1, wherein a cross section of the at least one detection structure is a square with each side having a length of 10 μm to 200 μm, and a height of the at least one detection structure is 1 μm to 10 μm.

9. The display substrate according to claim 1, further comprising:
a retainer wall arranged at the peripheral region and surrounding the display element; and
an anti-cracking groove arranged at a side of the retainer wall away from the display element, wherein the at least one detection structure is arranged between the retainer wall and the anti-cracking groove.

10. The display substrate according to claim 9, wherein a distance between the at least one detection structure and a side of the retainer wall away from the display element is 10 μm to 150 μm.

11. A detection method for the display substrate according to claim 1, comprising:
prior to formation of the thin film encapsulation layer, transmitting a light beam to the at least one detection structure, receiving a first reflected light beam reflected from the at least one detection structure, and recording a first optical parameter of the first reflected light beam;
subsequent to the formation of the thin film encapsulation layer on the display element, transmitting the light beam to the at least one detection structure, receiving a second reflected light beam reflected from at least one detection structure, and recording a second optical parameter of the second reflected light beam; and
comparing the first optical parameter with the second optical parameter, and when the first optical parameter is different from the second optical parameter, determining that at least one detection structure is covered by the thin film encapsulation layer.

12. The detection method according to claim 11, further comprising:
subsequent to the formation of an organic material layer of the thin film encapsulation layer and prior to completion of the formation of the thin film encapsulation layer on the display element, transmitting the light beam to the at least one detection structure, receiving a third reflected light beam reflected from the at least one detection structure, and recording a third optical parameter of the third reflected light beam; and
subsequent to recording the second optical parameter of the second reflected light beam, comparing the second optical parameter with the third optical parameter, and when the second optical parameter is identical to the third optical parameter, determining that an organic material of the organic material layer overflows; or
subsequent to recording the second optical parameter of the second reflected light beam, acquiring a first difference between a first parameter in the second optical parameter and the first parameter in the first optical parameter, acquiring a second difference between the first parameter in the third optical parameter and the first parameter in the first optical parameter, comparing the first difference with the second difference, and when the first difference is identical to the second difference, determining that the organic material of the organic material layer overflows.

13. A detection apparatus for the display substrate according to claim 1, comprising:
a detection light source configured to transmit a light beam to the at least one detection structure; and
a reception device configured to receive a reflected light beam reflected from the at least one detection structure, and determine whether the at least one detection structure is covered by the thin film encapsulation layer in accordance with the reflected light beam reflected from the at least one detection structure.

14. The detection apparatus according to claim 13, wherein the reception device is further configured to:
prior to a formation of the thin film encapsulation layer, receive a first reflected light beam reflected from the at least one detection structure, and acquire a first optical parameter of the first reflected light beam;
subsequent to the formation of the thin film encapsulation layer on the display element, receive a second reflected light beam reflected from the at least one detection structure, and acquire a second optical parameter of the second reflected light beam; and
when the first optical parameter is different from the second optical parameter, determine that at least one detection structure is covered by the thin film encapsulation layer.

15. The detection apparatus according to claim 14, wherein the reception device is further configured to:
subsequent to the formation of an organic material layer of the thin film encapsulation layer and prior to completion of the formation of the thin film encapsulation layer on the display element, receive a third reflected light beam reflected from the at least one detection structure, acquire a third optical parameter of the third reflected light beam, and when the second optical parameter is identical to the third optical parameter, determine that an organic material of the organic material layer overflows; or
subsequent to recording the second optical parameter of the second reflected light beam, acquire a first difference between a first parameter in the second optical parameter and the first parameter in the first optical parameter, acquire a second difference between the first parameter in the third optical parameter and the first parameter in the first optical parameter, compare the first difference with the second difference, and when the first difference is identical to the second difference, determine that the organic material of the organic material layer overflows.
